(19) United States
(12) Patent Application Publication
(10) Pub. No.: US 2025/0191918 A1
(43) Pub. Date: Jun. 12, 2025

(54) DIELECTRIC STRUCTURE, SEMICONDUCTOR DEVICE STRUCTURE, AND MANUFACTURING METHODS THEREFOR

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/924,940

(22) Filed: Oct. 23, 2024

(30) Foreign Application Priority Data
Dec. 8, 2023 (CN) 202311685105.0

(51) Int. Cl. H01L 21/04; H01L 21/02; H01L 29/16; H01L 29/51; H01L 29/66; H01L 29/78

(52) U.S. Cl. CPC H01L 21/049; H01L 21/02236; H10D 12/031; H10D 30/668; H10D 62/8325; H10D 64/691

(57) ABSTRACT

Disclosed are a dielectric structure, a semiconductor device structure, and manufacturing methods therefor. The manufacturing method for the dielectric structure includes: performing Al doping to a surface of a SiC substrate to form an Al-doped SiC layer and then oxidizing the Al-doped SiC layer to form a dielectric layer including at least a SiAlO layer. On one hand, thermal oxidation temperature required for oxidizing SiC to SiO₂ may be reduced, so that an interface state with a high density at an interface of SiC/SiO₂ is reduced, and quality of the dielectric layer is improved. On the other hand, original Si in the SiO₂ is replaced with Al, a more stable structure may be formed, and the quality of the dielectric layer is further improved.

### CROSS-REFERENCE TO RELATED APPLICATIONS

This application claims priority to Chinese Patent Application No. 202311685105.0, filed on Dec. 8, 2023, which is hereby incorporated by reference in its entirety.

### TECHNICAL FIELD

The present disclosure relates to the field of semiconductor technologies, and in particular, to a dielectric structure, a semiconductor device structure, and manufacturing methods therefor.

### BACKGROUND

Due to characteristics of high breakdown strength, high electron drift velocity, and high thermal conductivity, SiC material is suitable for preparation of a high-power device. As a typical representative of the third-generation semiconductor, SiC material has excellent physical and chemical properties and is an ideal material for manufacturing a device with characteristics of high-temperature-resistance, high-power, high-frequency, and high-irradiation-resistance. Although SiC Power MOSFET (Metal-Oxide-Semiconductor Field Effect Transistor) has been commercialized, research on gate dielectrics of the SiC Power MOSFET is still of great significance. The gate dielectric is critical in a SiC MOS device because the gate dielectric is required to maintain a high electric field intensity and a low gate leakage current.

### SUMMARY

In view of this, embodiments of the present disclosure provide a dielectric structure, a semiconductor device structure, and manufacturing methods for therefor, so as to improve quality of a gate dielectric layer in a SiC MOS device.

According to an aspect of the present disclosure, an embodiment of the present disclosure provides a manufacturing method for a dielectric structure. The method includes: providing a SiC substrate, wherein the SiC substrate has a first surface and a second surface corresponding to each other; performing Al doping to at least part of the first surface of the SiC substrate to form an Al-doped SiC layer; and oxidizing the Al-doped SiC layer through a thermal oxidation process to form a dielectric layer on the SiC substrate, wherein the dielectric layer includes at least a SiAlO layer.

According to another aspect of the present disclosure, an embodiment of the present disclosure provides a manufacturing method for a semiconductor device structure. The method includes any one of the manufacturing methods for the dielectric structure mentioned above. The step of providing a SiC substrate includes: providing a SiC substrate of a first conductivity type, the SiC substrate having a first surface and a second surface corresponding to each other; forming a well region of a second conductivity type at two ends of the first surface of the SiC substrate; forming a source region of the first conductivity type in the first surface of the well region; and forming a heavily doped drain region of the first conductivity type in the second surface of the SiC substrate, where after the oxidizing the Al-doped SiC layer through a thermal oxidation process to form a dielectric layer on the SiC substrate, the method further includes: performing etching to the dielectric layer in a non-gate region to expose the source region; and disposing a source electrode in the source region, disposing a drain electrode in the drain region, and disposing a gate electrode on the dielectric layer.

According to still another aspect of the present disclosure, an embodiment of the present disclosure provides a manufacturing method for a semiconductor device structure. The method includes any one of the manufacturing methods for the dielectric structure mentioned above. The step of providing a SiC substrate includes: providing a SiC substrate of a first conductivity type, the SiC substrate having a first surface and a second surface corresponding to each other; performing etching to the first surface of the SiC substrate to form a trench, where the performing Al doping to at least part of the first surface of the SiC substrate to form an Al-doped SiC layer includes: performing Al doping to a side wall and a bottom of the trench to form an Al-doped SiC layer; and after the oxidizing the Al-doped SiC layer through a thermal oxidation process to form a dielectric layer on the SiC substrate, the method further includes: forming a well region of a second conductivity type in the first surface of the SiC substrate; forming a source region of the first conductivity type in the first surface of a side, closer to the dielectric layer, of the well region; forming a heavily doped drain region of the first conductivity type in the second surface of the SiC substrate; and disposing a gate electrode in a groove of the dielectric layer, disposing a source electrode in the source region, and disposing a drain electrode in the drain region.

According to yet still another aspect of the present disclosure, an embodiment of the present disclosure provides a dielectric structure, prepared by any one of the manufacturing method for the dielectric structure mentioned above, including a SiC substrate and a dielectric layer stacked in layers, where the dielectric layer includes at least a SiAlO layer.

According to yet still another aspect of the present disclosure, an embodiment of the present disclosure provides a semiconductor device structure prepared by any one of the manufacturing methods for the semiconductor device structure mentioned above. The semiconductor device structure includes: a SiC substrate of a first conductivity type, the SiC substrate having a first surface and a second surface corresponding to each other; a well region of a second conductivity type located at two ends of the first surface of the SiC substrate; a source region of the first conductivity type located in the first surface of the well region and a source electrode in contact with the source region; a heavily doped drain region of the first conductivity type located in the second surface of the SiC substrate and a drain electrode in contact with the drain region; and a dielectric layer and a gate electrode located in a gate region of the first surface of the SiC substrate, where the dielectric layer includes at least a SiAlO layer.

According to yet still another aspect of the present disclosure an embodiment of the present disclosure provides a semiconductor device structure prepared by any one of the manufacturing methods for the semiconductor device structure mentioned above. The semiconductor device structure includes: a SiC substrate of a first conductivity type, where the SiC substrate has a first surface and a second surface corresponding to each other and the first surface of the SiC substrate is provided with a trench; a well region of a second conductivity type located in the first surface of the SiC substrate; a source region of the first conductivity type located in the first surface of a side, closer to the trench, of the well region, and a source electrode in contact with the source region; a heavily doped drain region of the first conductivity type located in the second surface of the SiC substrate and a drain electrode in contact with the drain region; and a dielectric layer located on a side wall and a bottom of the trench, and a gate electrode in a groove of the dielectric layer, wherein the dielectric layer includes at least a SiAlO layer.

### BRIEF DESCRIPTION OF THE DRAWINGS

FIG. 1 is a flowchart of a manufacturing method for a dielectric structure according to an embodiment of the present disclosure.

FIGS. 2 to 4 are schematic diagrams of intermediate structures corresponding to the process shown in FIG. 1.

FIG. 5 is a schematic structural diagram of a dielectric structure according to an embodiment of the present disclosure.

FIG. 6 is a schematic structural diagram of a dielectric structure before oxidation according to an embodiment of the present disclosure.

FIG. 7 is a schematic structural diagram of a dielectric structure after oxidation according to an embodiment of the present disclosure.

FIG. 8 is a schematic structural diagram of a dielectric structure before oxidation according to an embodiment of the present disclosure.

FIG. 9 is a flowchart of a manufacturing method for a semiconductor device structure according to an embodiment of the present disclosure.

FIGS. 10 to 16 are schematic diagrams of intermediate structures corresponding to the process shown in FIG. 9.

FIG. 17 is a flowchart of a manufacturing method for a semiconductor device structure according to an embodiment of the present disclosure.

FIGS. 18 to 25 are schematic diagrams of intermediate structures corresponding to the process shown in FIG. 17.

FIG. 26 is a flowchart of a manufacturing method for a dielectric structure according to another embodiment of the present disclosure.

FIG. 27 is a flowchart of a manufacturing method for a dielectric structure according to still another embodiment of the present disclosure.

### DETAILED DESCRIPTION OF THE EMBODIMENTS

Technical solutions in the embodiments of the present disclosure are clearly and completely described below with reference to accompanying drawings in the embodiments of the present disclosure. Obviously, the described embodiments are only a part of embodiments of the present disclosure, not all of them. Based on the embodiments of the present disclosure, all other embodiments obtained by a person of ordinary skill in the art without creative efforts shall fall within protection scope of the present disclosure.

During a manufacture process of a SiC MOS device, a gate dielectric layer with low quality greatly limits performance of the SiC MOS device. For example, when a SiO₂ gate dielectric layer is obtained by means of direct thermal oxidation growth of SiC, an interface between SiC and the SiO₂ gate dielectric layer often inevitably has many interface defects, so that a channel mobility is greatly reduced.

In order to reduce a large number of interface states existing between SiC and SiO₂ grown by a traditional direct thermal oxidation method, improve the channel mobility, and improve forward conduction capability of the device, the present disclosure provides a dielectric structure, a semiconductor device structure, and manufacturing methods therefor. Al doping is performed to a surface of a SiC substrate to form an Al-doped SiC layer, and then the Al-doped SiC layer is oxidized to form a dielectric layer including at least a SiAlO layer. According to the present disclosure, by performing Al doping to the surface of the SiC substrate, on one hand, thermal oxidation temperature required for oxidizing SiC to SiO₂ may be reduced, so that an interface state with a high density at an interface of SiC/SiO₂ is reduced, and quality of the dielectric layer is improved; and on the other hand, original Si in the SiO₂ is replaced with Al, a more stable structure may be formed, and the quality of the dielectric layer is further improved. According to the dielectric layer provided by the present disclosure, a large number of interface states existing between SiC and SiO₂ grown by a traditional direct thermal oxidation method are reduced, thereby increasing a channel mobility, and improving forward conduction capability of a device.

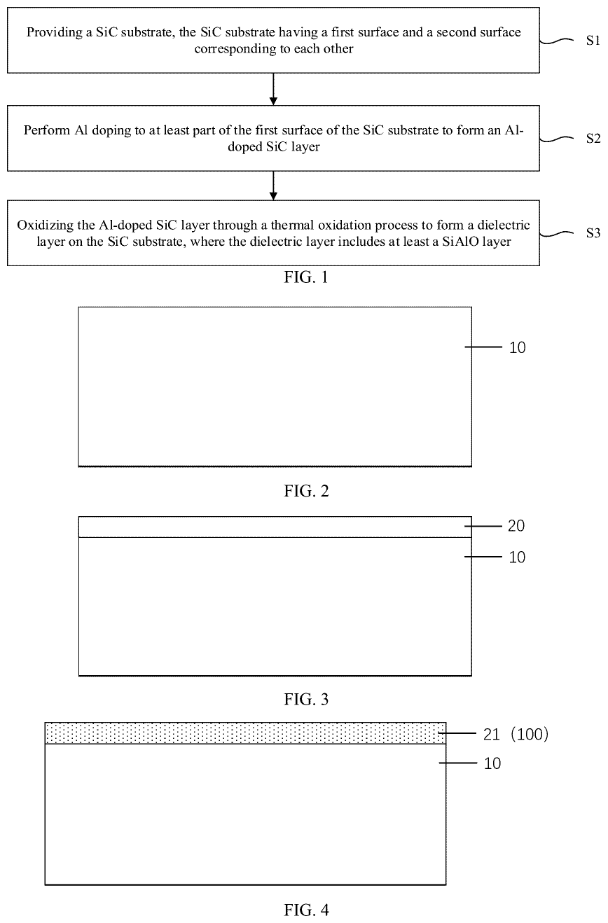

A dielectric structure, a semiconductor device structure, and manufacturing methods therefor mentioned in the present disclosure will be described through embodiments with reference to FIGS. 1 to 27 in the following.

FIG. 1 is a flowchart of a manufacturing method for a dielectric structure according to an embodiment of the present disclosure. FIGS. 2 to 4 are schematic diagrams of intermediate structures corresponding to the process shown in FIG. 1.
Step S1: providing a SiC substrate, the SiC substrate having a first surface and a second surface corresponding to each other.
Step S2: perform Al doping to at least part of the first surface of the SiC substrate to form an Al-doped SiC layer.
Step S3: oxidizing the Al-doped SiC layer through a thermal oxidation process to form a dielectric layer on the SiC substrate, where the dielectric layer includes at least a SiAlO layer.

Specifically, as shown in FIG. 2, a SiC substrate 10 is provided. The SiC substrate 10 has a first surface and a second surface corresponding to each other. As shown in FIG. 3, Al doping is performed to at least part of the first surface of the SiC substrate 10 to form an Al-doped SiC layer 20, and a concentration of Al ions doped in the SiC substrate 10 is greater than 1E15/cm3. As shown in FIG. 4, a dielectric layer 100 on the SiC substrate 10 is formed by oxidizing the Al-doped SiC layer 20 through a thermal oxidation process, and the dielectric layer 100 includes at least a SiAlO layer 21.

Generally, due to high chemical stability (high atomic density and short chemical bond length) of SiC, thermal oxidation temperature (from 1200° C. to 1400° C.) of SiC is very high. The high thermal oxidation temperature brings defects of a process introduction type, including problems such as a deep-level trap and surface quality degradation, resulting in an interface state with a high density at the interface of SiC/SiO₂. In the present embodiment, a surface of the SiC substrate 10 is doped with enough Al, and a concentration of doped Al ions is greater than 1E15/cm³, so that a thermal oxidation temperature required for oxidizing SiC to SiO₂ may be reduced, thereby reducing the interface state with the high density at the interface of SiC/SiO₂ and improving quality of the dielectric layer 100. Meanwhile, original Si in the SiO₂ is replaced with Al, so that a more stable structure may be formed, and the quality of the dielectric layer 100 is further improved. According to the dielectric layer 100 prepared according to the present embodiment, a large number of interface states existing between SiC and SiO₂, caused by a traditional direct thermal oxidation method, are reduced, thereby increasing channel mobility, and improving forward conduction capability of a device.

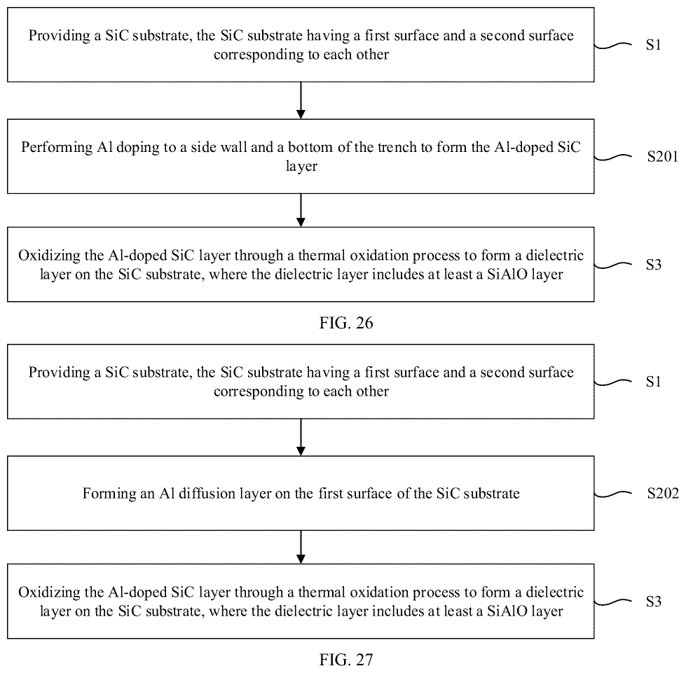

In an embodiment, FIG. 5 is a schematic structural diagram of a dielectric structure provided by an embodiment of the present disclosure. As shown in FIG. 5, the first surface of the SiC substrate 10 is provided with a trench 101 recessed inward from the first surface. As shown in FIG. 26, Step S2 may includes the following step.

Step S201: performing Al doping to a side wall and a bottom of the trench to form the Al-doped SiC layer. And then the SiAlO layer 21 is formed on the side wall and the bottom of the trench 101 of the SiC substrate 10 through the thermal oxidation process. The dielectric structure provided in the present embodiment may be used to form a trench-type MOS device.

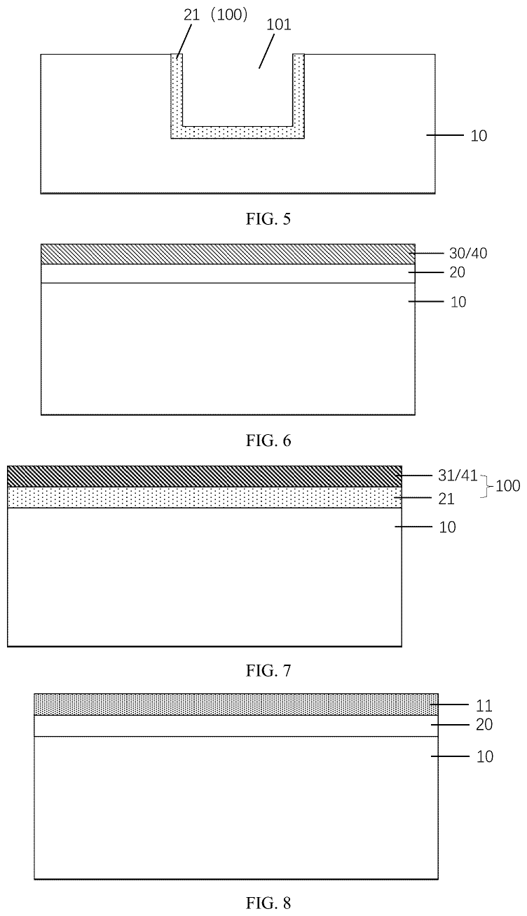

In an embodiment, FIG. 6 is a schematic structural diagram of a dielectric structure before oxidation according to an embodiment of the present disclosure, and FIG. 7 is a schematic structural diagram of a dielectric structure after oxidation according to an embodiment of the present disclosure. In Step S2, a method of performing Al doping to the first surface of the SiC substrate 10 is ion implantation. As shown in FIG. 6, after the first surface of the SiC substrate 10 is ion-implanted with Al, the method further include the following step before Step S3. Step S21: forming an AlN layer or a SiAlN layer on the Al-doped SiC layer. In Step S3, the Al-doped SiC layer 20 and the AlN layer 30 or the SiAlN layer 40 are oxidized simultaneously through the thermal oxidation process to form the dielectric layer 100 on the SiC substrate 10 as shown in FIG. 7. The the dielectric layer 100 includes a SiAlO layer 21 and an AlOxN layer 31 or a SiAlOxN layer 41. As the AlN layer 30 or the SiCAlN layer 40 is formed on the Al-doped SiC layer 20, the SiAlO layer 21 formed by oxidization to the Al-doped SiC layer 20 may contain nitrogen diffused from the AlN layer 30 or the SiCAlN layer 40. Nitrogen background concentration in the SiAlO layer 21 may further improve an interface characteristic of the SiAlO layer 21 and the SiC substrate 10, thereby further reducing the interface state with the high density existing at the interface of the SiC/SiO₂, thereby improving the quality of the dielectric layer 100.

In an embodiment, FIG. 8 is a schematic structural diagram of a dielectric structure before oxidation according to an embodiment of the present disclosure. As shown in FIG. 8, in Step S2, the method of performing doping to the first surface of the SiC substrate 10 may include the following step. As shown in FIG. 27, Step S202: forming an Al diffusion layer on the first surface of the SiC substrate. A material of the Al diffusion layer 11 includes Al alloy or AlN alloy. Further, the material of the Al diffusion layer 11 includes SiCAlN. The Al element in the Al diffusion layer 11 diffuses into the SiC substrate 10. Damage to crystal lattice of the SiC substrate 10 may be reduced through the diffusion method to perform Al doping to the first surface of the SiC substrate 10. The Al diffusion layer 11 in the present embodiment may be removed by etching, and may alternatively be retained and oxidized simultaneously with the Al-doped SiC layer 20, which is not specifically limited in the present disclosure.

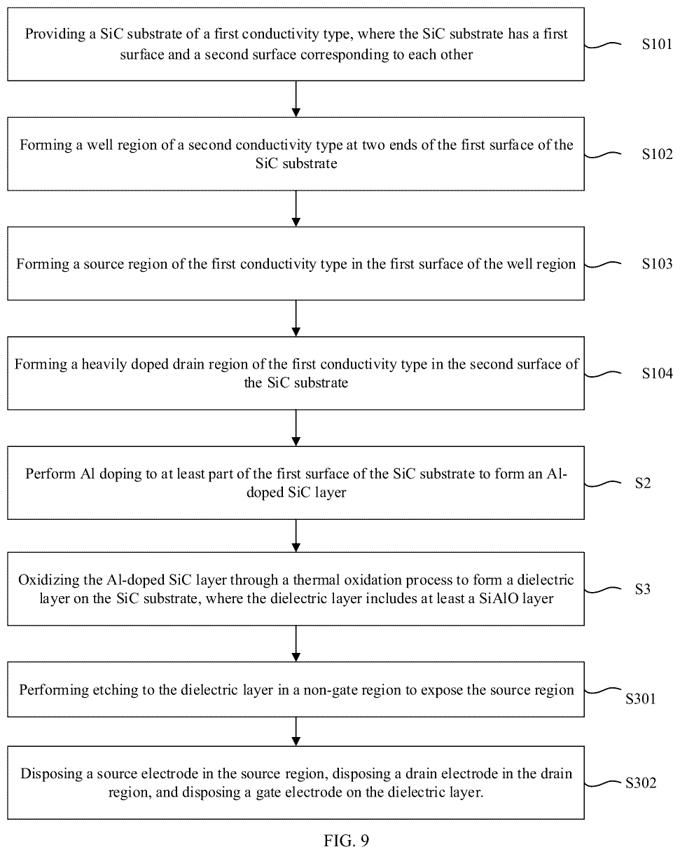

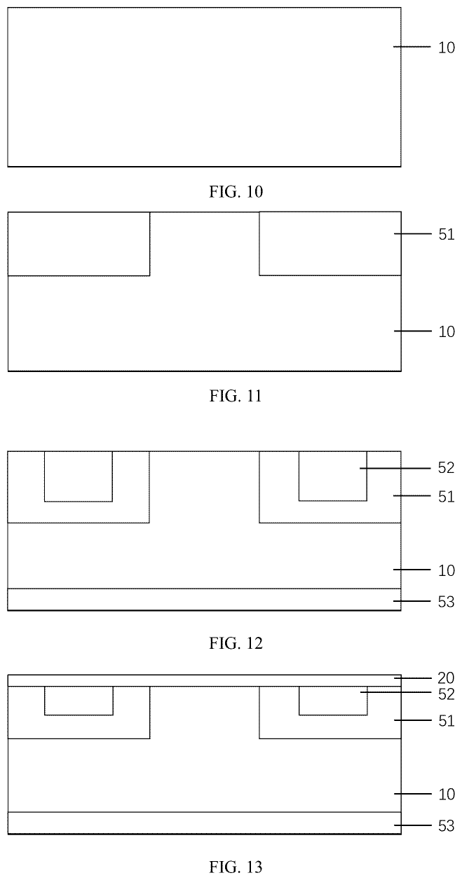

According to another aspect of the present disclosure, the present disclosure further provides a manufacturing method for a semiconductor device structure. FIG. 9 is a flowchart of a manufacturing method for a semiconductor device structure according to an embodiment of the present disclosure. FIGS. 10 to 16 are schematic diagrams of intermediate structures corresponding to the process shown in FIG. 9.
Step S101: providing a SiC substrate of a first conductivity type, where the SiC substrate has a first surface and a second surface corresponding to each other.
Step S102: forming a well region of a second conductivity type at two ends of the first surface of the SiC substrate.
Step S103: forming a source region of the first conductivity type in the first surface of the well region.
Step S104: forming a heavily doped drain region of the first conductivity type in the second surface of the SiC substrate.
Step S2: performing Al doping to the first surface of the SiC substrate to form an Al-doped SiC layer.
Step S3: oxidizing the Al-doped SiC layer through a thermal oxidation process to form a dielectric layer on the SiC substrate, where the dielectric layer includes at least a SiAlO layer.
Step S301: performing etching to the dielectric layer in a non-gate region to expose the source region.
Step S302: disposing a source electrode in the source region, disposing a drain electrode in the drain region, and disposing a gate electrode on the dielectric layer.

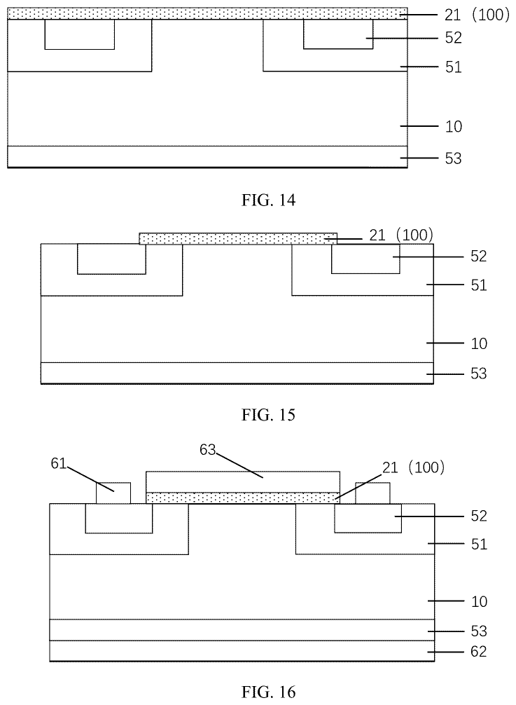

Specifically, as shown in FIG. 10, a SiC substrate 10 of a first conductivity type is provided, and the SiC substrate 10 has a first surface and a second surface corresponding to each other. As shown in FIG. 11, a well region 51 of a second conductivity type is formed at two ends of the first surface of the SiC substrate 10. As shown in FIG. 12, a source region 52 of the first conductivity type is formed in the first surface of the well region 51, and a heavily doped drain region 53 of the first conductivity type is formed in the second surface of the SiC substrate 10. As shown in FIG. 13, the first surface of the SiC substrate 10 is performed Al doping to form an Al-doped SiC layer 20. And the Al-doped SiC layer 20 is oxidized through a thermal oxidation process. As shown in FIG. 14, a dielectric layer 100 on the SiC substrate 10 is formed, and the dielectric layer 100 includes at least a SiAlO layer 21. As shown in FIG. 15, the dielectric layer 100 in a non-gate region is performed etching to expose the source region 52. A source electrode 61 is disposed in the source region 52, a drain electrode 62 is disposed in the drain region 53, and a gate electrode 63 is disposed on the dielectric layer 100 to form a semiconductor device structure as shown in FIG. 16. The well region 51, the source region 52 and the drain region 53 are formed by means of ion implantation or secondary epitaxy after selective etching. A method of forming the well region 51, the source region 52 and the drain region 53 is not specifically limited in the present disclosure. When the semiconductor device structure prepared through the method according to the present embodiment is applied to a SiC MOS device, a leakage current of a gate dielectric layer of the SiC MOS device may be reduced, and density of an interface state of SiC/SiO₂ is reduced, thereby improving a breakdown voltage of the SiC MOS device, and further improving reliability of the SiC MOS device during high-temperature and high-power application.

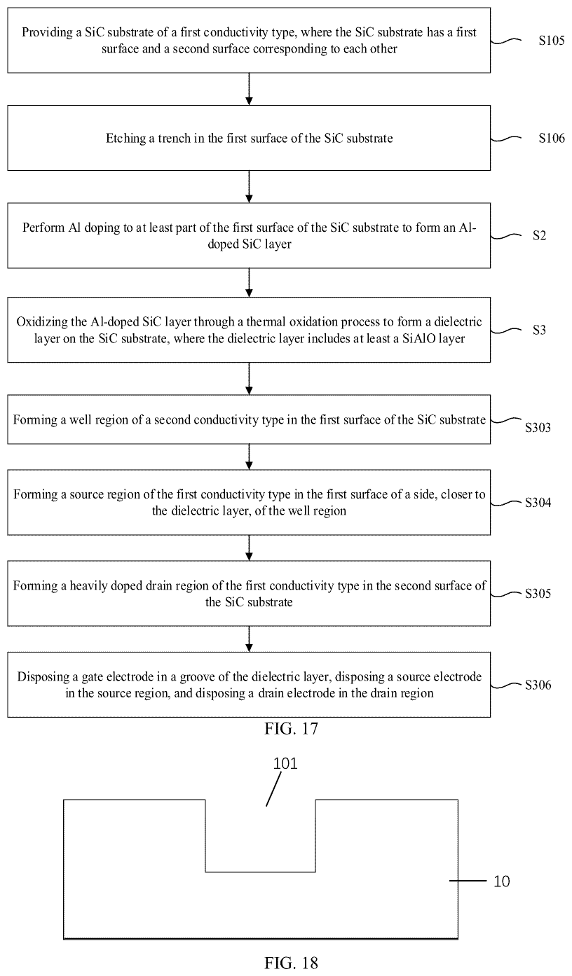

According to another aspect of the present disclosure, the present disclosure further provides a manufacturing method for a semiconductor device structure. FIG. 17 is a flowchart of a manufacturing method for a semiconductor device structure according to an embodiment of the present disclosure. FIG. 18 to FIG. 25 are schematic diagrams of intermediate structures corresponding to the process shown in FIG. 17.
Step S105: providing a SiC substrate of a first conductivity type, where the SiC substrate has a first surface and a second surface corresponding to each other.
Step S106: etching a trench in the first surface of the SiC substrate.
Step S2: performing doping to a side wall and a bottom of the trench with Al to form an Al-doped SiC layer.
Step S3: oxidizing the Al-doped SiC layer through a thermal oxidation process to form a dielectric layer on the SiC substrate, where the dielectric layer includes at least a SiAlO layer.
Step S303: forming a well region of a second conductivity type in the first surface of the SiC substrate.
Step S304: forming a source region of the first conductivity type in the first surface of a side, closer to the dielectric layer, of the well region.
Step S305: forming a heavily doped drain region of the first conductivity type in the second surface of the SiC substrate.
Step S306: disposing a gate electrode in a groove of the dielectric layer, disposing a source electrode in the source region, and disposing a drain electrode in the drain region.

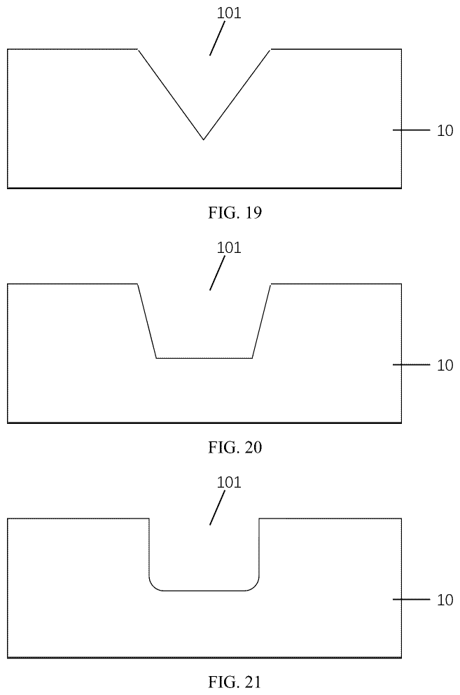

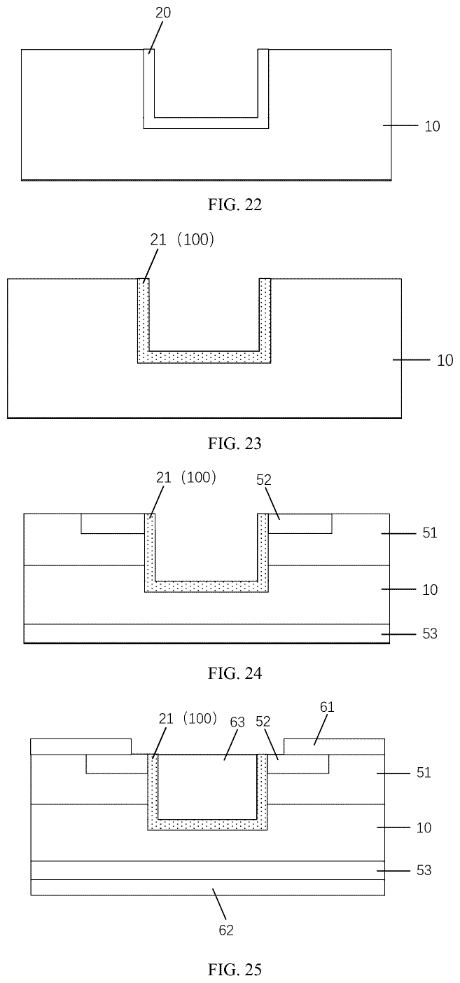

Specifically, as shown in FIG. 18, a SiC substrate 10 of a first conductivity type is provided, and the SiC substrate 10 has a first surface and second surface corresponding to each other. A trench 101 is etched on the first surface of the SiC substrate 10. A depth of the trench 101 is less than a thickness of the SiC substrate 10. A cross-sectional shape of the trench 101 includes a rectangle (as shown in FIG. 18), a V-shape (as shown in FIG. 19), or a trapezoid (as shown in FIG. 20). A bottom surface of the trench 101 may be performed secondary etching to form rounded corners (as shown in FIG. 21), so as to reduce electric field intensity at the bottom of the trench 101, thereby improving a breakdown voltage. As shown in FIG. 22, a side wall and the bottom of the trench 101 are performed Al doping to form an Al-doped SiC layer 20. The Al-doped SiC layer 20 is oxidized through a thermal oxidation process. As shown in FIG. 23, a dielectric layer 100 on the SiC substrate 10 is formed, and the dielectric layer 100 includes at least a SiAlO layer 21. As shown in FIG. 24, a well region 51 of a second conductivity type is formed in the first surface of the SiC substrate 10, and a thickness of the well region 51 is less than the depth of the trench 101. A source region 52 of the first conductivity type is formed in the first surface of a side, closer to the dielectric layer 100, of the well region 51, and a heavily doped drain region 53 of the first conductivity type is formed in the second surface of the SiC substrate 10. Finally, a gate electrode 63 is disposed in a groove of the dielectric layer 100, a source electrode 61 is disposed in the source region 52, and a drain electrode 62 is disposed in the drain region 53 to form a semiconductor device structure as shown in FIG. 25. When the semiconductor device structure prepared through the method according to the present embodiment is applied to a trench-type SiC MOS device, a leakage current of a gate dielectric layer of the SiC MOS device may be reduced, and density of an interface state of SiC/SiO₂ is reduced, thereby improving a breakdown voltage of the SiC MOS device, and further improving reliability of the SiC MOS device during high-temperature and high-power application.

According to another aspect of the present disclosure, the present disclosure further provides a dielectric structure. As shown in FIG. 4, the dielectric structure is a dielectric structure prepared by any one of the manufacturing methods for the dielectric structure mentioned above. The dielectric structure includes a SiC substrate 10 and a dielectric layer 100 stacked in layers. The dielectric layer 100 includes at least a SiAlO layer 21. A concentration of Al ions in the SiAlO layer 21 is greater than 1E15/cm³. The Al element in the SiAlO layer 21 may reduce an interface state at an interface between the SiC substrate 10 and the dielectric layer 100. And Si is replaced with Al to form a more stable structure, thereby improving quality of the dielectric layer 100.

In an embodiment, as shown in FIG. 7, the dielectric layer 100 further includes an AlOxN layer 31 or a SiAlOxN layer 41 on a side, away from the SiC substrate 10, of the SiAlO layer 21. By providing the AlOxN layer 31 or the SiAlOxN layer 41, Al content in the SiAlO layer 21 may be increased while introducing nitrogen background concentration, thereby reducing the interface state and improving the quality of the dielectric layer 100.

According to another aspect of the present disclosure, the present disclosure further provides a semiconductor device structure. As shown in FIG. 16, the semiconductor device structure includes: a SiC substrate 10 of a first conductivity type, where the SiC substrate 10 has a first surface and a second surface corresponding to each other; a well region 51 of a second conductivity type located at two ends of the first surface of the SiC substrate 10; a source region 52 of the first conductivity type located in the first surface of the well region 51 and a source electrode 61 in contact with the source region 52; a heavily doped drain region 53 of the first conductivity type located in the second surface of the SiC substrate 10 and a drain electrode 62 in contact with the drain region 53; and a dielectric layer 100 and a gate electrode 63 located in a gate region of the first surface of the SiC substrate 10, where the dielectric layer includes at least a SiAlO layer 21.

According to another aspect of the present disclosure, the present disclosure further provides a semiconductor device structure. As shown in FIG. 25, the semiconductor device structure includes: a SiC substrate 10 of a first conductivity type, where the SiC substrate 10 has a first surface and a second surface corresponding to each other, and the first surface of the SiC substrate 10 is provided with a trench 101; a well region 51 of a second conductivity type located in the first surface of the SiC substrate 10; a source region 52 of the first conductivity type located in the first surface of a side, close to the trench 101, of the well region 51, and a source electrode 61 in contact with the source region 52; a heavily doped drain region 53 of the first conductivity type located in the second surface of the SiC substrate 10 and a drain electrode 62 in contact with the drain region 53; and a dielectric layer 100 located on a side wall and a bottom of the trench 101, and a gate electrode 63 in a groove of the dielectric layer 100, where the dielectric layer 100 includes at least a SiAlO layer 21.

The present disclosure provides a manufacturing method for a dielectric layer. Al doping is performed to a surface of a SiC substrate to form an Al-doped SiC layer, and then the Al-doped SiC layer is oxidized to form a dielectric layer including at least a SiAlO layer. According to the present disclosure, by performing Al doping to the surface of the SiC substrate, on one hand, thermal oxidation temperature required for oxidizing SiC to SiO₂ may be reduced, so that an interface state with a high density at an interface of SiC/SiO₂ is reduced, and quality of the dielectric layer is improved; and on the other hand, original Si in the SiO₂ is replaced with Al, a more stable structure may be formed, and the quality of the dielectric layer is further improved. According to the dielectric layer provided by the present disclosure, a large number of interface states existing between SiC and SiO₂ grown by a traditional direct thermal oxidation method are reduced, thereby increasing a channel mobility, and improving forward conduction capability of a device.

It should be understood that the term “including” and variations of the term “including” used in the present disclosure are open-ended, meaning “including but not limited to”. The term “an embodiment” means “at least one embodiment”. The term “another embodiment” means “at least one further embodiment”. In the specification, the schematic expressions of the above terms do not necessarily refer to the same embodiments or examples. Moreover, the specific features, structures, materials, or characteristics described can be combined in any one or more embodiments or examples in an appropriate manner. In addition, technicians in this field can combine and integrate the different embodiments or examples described in the specification, as well as the features of different embodiments or examples, without conflicting with each other.

The above is only some preferred embodiments of the present disclosure and is not intended to limit the present disclosure. Any modifications, equivalent substitutions, and the like made within the spirit and principles of the present disclosure shall fall within the scope of protection of the present disclosure.

What is claimed is:

1. A manufacturing method for a dielectric structure, comprising:
providing a SiC substrate, wherein the SiC substrate has a first surface and a second surface corresponding to each other;
performing Al doping to at least part of the first surface of the SiC substrate to form an Al-doped SiC layer; and
oxidizing the Al-doped SiC layer through a thermal oxidation process to form a dielectric layer on the SiC substrate, wherein the dielectric layer comprises at least a SiAlO layer.

2. The manufacturing method for the dielectric structure according to claim 1, wherein the first surface of the SiC substrate is provided with a trench recessed inward from the first surface; and
the performing Al doping to at least part of the first surface of the SiC substrate to form an Al-doped SiC layer comprises:
performing Al doping to a side wall and a bottom of the trench to form the Al-doped SiC layer.

3. The manufacturing method for the dielectric structure according to claim 1, wherein a method of the performing Al doping to the first surface of the SiC substrate is ion implantation.

4. The manufacturing method for the dielectric structure according to claim 3, before the oxidizing the Al-doped SiC layer through a thermal oxidation process to form a dielectric layer on the SiC substrate, further comprising:
forming an AlN layer or a SiCAlN layer on the Al-doped SiC layer.

5. The manufacturing method for the dielectric structure according to claim 4, wherein the oxidizing the Al-doped SiC layer through a thermal oxidation process to form a dielectric layer on the SiC substrate comprises:
simultaneously oxidizing the Al-doped SiC layer and the AlN layer or the SiCAlN layer through the thermal oxidation process to form the dielectric layer on the SiC substrate, wherein the dielectric layer comprises the SiAlO layer and an AlO_{X}N layer or a SiAlO_{X}N layer.

6. The manufacturing method for the dielectric structure according to claim 5, wherein the SiAlO layer comprises nitrogen element.

7. The manufacturing method for the dielectric structure according to claim 1, wherein the performing Al doping to at least part of the first surface of the SiC substrate to form an Al-doped SiC layer comprises:
forming an Al diffusion layer on the first surface of the SiC substrate to form the Al-doped SiC layer, wherein Al is diffused from the Al diffusion layer into the SiC substrate.

8. The manufacturing method for the dielectric structure according to claim 7, wherein a material of the Al diffusion layer comprises Al alloy or AlN alloy.

9. The manufacturing method for the dielectric structure according to claim 7, wherein a material of the Al diffusion layer comprises SiCAlN.

10. A manufacturing method for a semiconductor device structure, comprising the manufacturing method for the dielectric structure according to claim 1, wherein the providing a SiC substrate comprises:
providing a SiC substrate of a first conductivity type, wherein the SiC substrate has a first surface and a second surface corresponding to each other;
forming a well region of a second conductivity type at two ends of the first surface of the SiC substrate;
forming a source region of the first conductivity type in the first surface of the well region; and
forming a heavily doped drain region of the first conductivity type in the second surface of the SiC substrate;
wherein after the oxidizing the Al-doped SiC layer through a thermal oxidation process to form a dielectric layer on the SiC substrate, the method further comprises:
performing etching to the dielectric layer in a non-gate region to expose the source region; and
disposing a source electrode in the source region, disposing a drain electrode in the drain region, and disposing a gate electrode on the dielectric layer.

11. The method for manufacturing the semiconductor device structure according to claim 10, wherein the well region, the source region and the drain region are formed by means of ion implantation or secondary epitaxy after selective etching.

12. A manufacturing method for a semiconductor device structure, comprising the manufacturing method for the dielectric structure according to claim 1, wherein the providing a SiC substrate comprises:
providing a SiC substrate of a first conductivity type, wherein the SiC substrate has a first surface and a second surface corresponding to each other; and
etching a trench in the first surface of the SiC substrate;
wherein the performing Al doping to at least part of the first surface of the SiC substrate to form an Al-doped SiC layer comprises:
performing Al doping to a side wall and a bottom of the trench to form an Al-doped SiC layer;
wherein after the oxidizing the Al-doped SiC layer through a thermal oxidation process to form a dielectric layer on the SiC substrate, the method further comprises:
forming a well region of a second conductivity type in the first surface of the SiC substrate;
forming a source region of the first conductivity type in the first surface of a side, closer to the dielectric layer, of the well region;
forming a heavily doped drain region of the first conductivity type in the second surface of the SiC substrate; and
disposing a gate electrode in a groove of the dielectric layer, disposing a source electrode in the source region, and disposing a drain electrode in the drain region.

13. The manufacturing method for the semiconductor device structure according to claim 12, wherein a cross-sectional shape of the trench comprises a rectangle, a V-shape, or a trapezoid.

14. The method for manufacturing the semiconductor device structure according to claim 12, wherein a bottom surface of the trench is provided with rounded corners through secondary etching.

15. A dielectric structure, prepared by the manufacturing method for the dielectric structure according to claim 1, comprising a SiC substrate and a dielectric layer stacked in layers, wherein the dielectric layer comprises at least a SiAlO layer.

16. The dielectric structure according to claim 15, wherein a concentration of Al ions in the SiAlO layer is greater than 1E15/cm³.

17. The dielectric structure according to claim 15, wherein the dielectric layer further comprises an AlO_{X}N layer or a SiAlO_{X}N layer located on a side, away from the SiC substrate, of the SiAlO layer.

18. The dielectric structure according to claim 15, wherein the SiAlO layer comprises nitrogen element.

19. A semiconductor device structure, prepared by the manufacturing method for the semiconductor device structure according to claim 10, comprising:
a SiC substrate of a first conductivity type, wherein the SiC substrate has a first surface and a second surface corresponding to each other;
a well region of a second conductivity type located at two ends of the first surface of the SiC substrate;
a source region of the first conductivity type located in the first surface of the well region and a source electrode in contact with the source region;
a heavily doped drain region of the first conductivity type located in the second surface of the SiC substrate and a drain electrode in contact with the drain region; and
a dielectric layer and a gate electrode located in a gate region of the first surface of the SiC substrate, wherein the dielectric layer comprises at least a SiAlO layer.

20. A semiconductor device structure, prepared by the manufacturing method for the semiconductor device structure according to claim 12, comprising:
a SiC substrate of a first conductivity type, wherein the SiC substrate has a first surface and a second surface corresponding to each other, and the first surface of the SiC substrate is provided with a trench;
a well region of a second conductivity type located in the first surface of the SiC substrate;
a source region of the first conductivity type located in the first surface of a side, closer to the trench, of the well region, and a source electrode in contact with the source region;
a heavily doped drain region of the first conductivity type located in the second surface of the SiC substrate and a drain electrode in contact with the drain region; and
a dielectric layer located on a side wall and a bottom of the trench, and a gate electrode located in a groove of the dielectric layer, wherein the dielectric layer comprises at least a SiAlO layer.
